(19) United States
(12) Patent Application Publication
(10) Pub. No.: US 2014/0140012 A1
(43) Pub. Date: May 22, 2014

(54) MODULE STRUCTURE

(71) Applicants: Industrial Technology Research Institute, (US); KUO HSIN TECHNOLOGY CO., LTD., Kaohsiung (TW)

(72) Inventors: Wen-Hsien WANG, Jiali Township (TW); Min-Tsung KUAN, Qingshui Township (TW); Tzong-Ming LEE, Hsinchu City (TW); Wen-Hsien CHOU, Lunbei Township (TW); Fu-Ming LIN, Zhudong Township (TW); Wen-Kuei LEE, Puyan Township (TW); Chin Zeng YEH, Kaohsiung City (TW); Ming-Hung CHEN, Kaohsiung City (TW)

(73) Assignees: KUO HSIN TECHNOLOGY CO., LTD., Kaohsiung (TW); INDUSTRIAL TECHNOLOGY RESEARCH INSTITUTE, Chutung (TW)

(21) Appl. No.: 13/790,743

(22) Filed: Mar. 8, 2013

(30) Foreign Application Priority Data
Nov. 20, 2012 (TW) 101143193

(51) Int. Cl. H05K 5/02

(52) U.S. Cl. CPC H05K 5/02
USPC 361/728

(57) ABSTRACT

Disclosed is a module structure including a front sheet, a back sheet, and an optotronic device disposed between the front sheet and the back sheet. A first encapsulate layer is disposed between the optotronic device and the front sheet. A second encapsulate layer is disposed between the optotronic device and the back sheet. The back sheet is a layered structure of a hydrogenated styrene elastomer resin layer and a polyolefin layer, wherein the hydrogenated styrene elastomer resin layer is disposed between the second encapsulate layer and the polyolefin layer.

### CROSS REFERENCE TO RELATED APPLICATIONS

The present application is based on, and claims priority from, Taiwan (International) Application Serial Number 101143193, filed on Nov. 20, 2012, the disclosure of which is hereby incorporated by reference herein in its entirety

### TECHNICAL FIELD

The technical field relates to a module structure, and in particular, to a back sheet thereof.

### BACKGROUND

A general module structure in solar cell includes a glass front sheet, an ethylene-vinylene acetate (EVA) copolymer encapsulate film, a solar cell, another EVA copolymer encapsulate film, and a back sheet from top to bottom. The EVA copolymer encapsulate films may fasten the solar cell, connect to circuit lines, insulate and protect the solar cell, and maintain solar cell performance after a long time use. The back sheet may provide electrical insulation, thermo resistance, and moisture resistance to expand the lifetime of the module structure of the solar cell.

Existing back sheets are composed of fluorinated resin films and a polyethylene terephthalate (PET) film. The fluorinated resin films are usually coated on two sides of the PET film to meet the requirement of moisture resistance and the likes. In addition, the adhesive coating layer is utilized to provide a sufficient adhesion between the fluorinated resin film and the EVA copolymer encapsulate film.

Accordingly, developing a novel back sheet structure is called-for.

### SUMMARY

One embodiment of the disclosure provides a module structure, comprising: a front sheet; a back sheet opposite to the front sheet; an optotronic device disposed between the front sheet and the back sheet; a first encapsulate layer disposed between the optotronic device and the front sheet; and a second encapsulate layer disposed between the optotronic device and the back sheet, wherein the back sheet is a layered structure of a hydrogenated styrene elastomer resin layer and a polyolefin layer, and the hydrogenated styrene elastomer resin layer is disposed between the second encapsulate layer and the polyolefin layer.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 shows a module structure in one embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

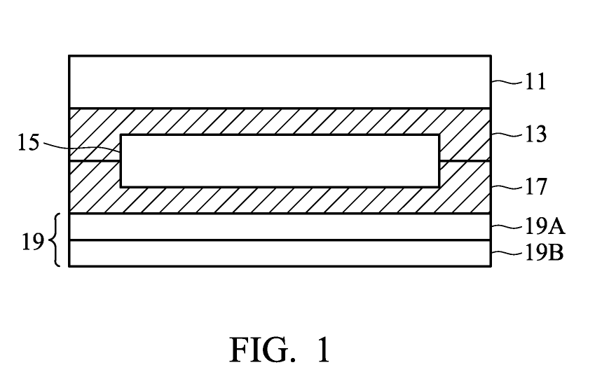

FIG. 1 shows a module structure in one embodiment of the disclosure. From top to bottom, the module structure includes a front sheet 11, a first encapsulate layer 13, an optotronic device 15, a second encapsulate layer 17, and a back sheet 19. The front sheet 11 can be glass, ethylene tetrafluoroethylene (ETFE), polyacrylate, or other transparent materials. In one embodiment, the first and second encapsulate layers 13 and 17 can be made of EVA copolymer. As shown in FIG. 1, the back sheet 19 is a layered structure of a hydrogenated styrene elastomer resin layer 19A and a polyolefin layer 19B, wherein the hydrogenated styrene elastomer resin layer 19A is disposed between the second encapsulate layer 17 and the polyolefin layer 19B. Compared to the PET film in the conventional back sheet, the polyolefin layer 19B has lower moisture absorption, higher hydrolysis resistance, higher electrical insulation, and higher climate resistance. The hydrogenated styrene elastomer resin layer 19A may serve as an adhesive layer between the polyolefin layer 19B and the second encapsulate layer 17. In one embodiment, an additional protective film (e.g. fluorinated resin film) attached thereon may be omitted from the polyolefin layer 19B. In addition, the polyolefin layer 19B and the hydrogenated styrene elastomer resin layer 19A can be co-extruded to form a bi-layered structure for saving process steps and time for manufacture.

In one embodiment, the optotronic device 15 is a solar cell. Alternatively, the optotronic device 15 can be, but not limited to, an organic light-emitting diode (OLED) or a liquid crystal display (LCD).

In one embodiment, the hydrogenated styrene elastomer resin layer 19A can be poly(styrene-b-isoprene), poly(styrene-b-isoprene-b-styrene, poly(styrene-b-butadiene-b-styrene), poly(styrene-b-isoprene/butadiene-b-styrene, or poly(styrene-b-vinyl bonded rich polyisoprene). The hydrogenated styrene elastomer resin layer 19A contains 10 wt % to 35 wt % of a polystyrene block. In one embodiment, the hydrogenated styrene elastomer resin layer 19A contains 13 wt % to 30 wt % of a polystyrene block. An overly low polystyrene block ratio may degrade the hardness and the mechanical tensile strength of the copolymer. An overly high polystyrene block ratio may improve the hardness and the mechanical tensile strength of the copolymer, however, the flowability and the related processibility of the copolymer is lowered, and the glass transfer temperature (Tg) of the copolymer is increased to reduce the adhesive property of the copolymer. The molecular weight and melt index of the hydrogenated styrene elastomer resin layer 19A have a negative correlation. In short, a higher melt index means a lower molecular weight. For example, the hydrogenated styrene elastomer resin layer 19A with a lower melt index has a higher molecular weight. In one embodiment, the hydrogenated styrene elastomer resin layer 19A has a melt index of about 1.0 g/10 min to 8 g/10 min, or of about 3.5 g/10 min to 6.5 g/10 min. The hydrogenated styrene elastomer resin layer 19A with an overly low melt index may have flowability which is too low to form a film with a uniform thickness. The hydrogenated styrene elastomer resin layer 19A with an overly high melt index may have flowability which is too high for separation from other films, and it may mix with the other films.

The polyolefin layer 19B can be polyethylene, polypropylene, ethylene-propylene copolymer, or multi-layered structures thereof. The molecular weight and melt index of the polyolefin layer 19B have a negative correlation. In short, a higher melt index means a lower molecular weight. For example, the polyolefin layer 19B with a lower melt index has a higher molecular weight. In one embodiment, the polyolefin layer 19B has a melt index of about 1.0 g/10 min to 8 g/10 min. The polyolefin layer 19B with an overly low melt index may have flowability which is too low to form a film with a uniform thickness. The polyolefin layer 19B with an overly high melt index may have flowability which is too high for separation from other films, and it may mix with the other films.

In one embodiment, the back sheet 19 has a thickness of about 0.2 mm to 0.6 mm. The optotronic device 15 in the module structure including an overly thin back sheet 19 is easily degraded by moisture. The module structure including an overly thick back sheet 19 has a higher cost and extra weight. In one embodiment, the hydrogenated styrene elastomer resin layer 19A and the polyolefin layer 19B have a thickness ratio of about 1:1 to 1:10, or of about 1:3 to 1:5. An overly thin hydrogenated styrene elastomer resin layer 19A will make it difficult for the polyolefin layer 19B to adhere to the second encapsulate layer 17. When the thickness of the back sheet 19 is a constant, an overly thick hydrogenated styrene elastomer resin layer 19A means an overly thin polyolefin layer 19B, which cannot efficiently protect the optotronic device 15.

In one embodiment, a reflectivity modifier, pigment, anti-oxidant, or combinations thereof can be further added into the hydrogenated styrene elastomer resin layer 19A and/or the polyolefin layer 19B of the back sheet 19. The reflectivity modifier such as metal oxide (e.g. titanium oxide, magnesium oxide, clay, or combinations thereof), calcium carbonate, silicon oxide, or combinations thereof may enhance the reflectivity of the module structure, thereby further increasing the conversion efficiency of the solar cell (optotronic device 15). A pigment such as carbon black or pigment masterbatch (e.g. CLARIANT REMAFI, polyolefin masterbatch) may change the color appearance of the module structure to match the building style. An anti-oxidant such as dibutyl hydroxyl toluene (BHT), bis(2,2,6,6-tetramethyl-4-piperidyl)sebacate, benzophenonone, derivatives thereof, or combinations thereof may prevent the yellowness of the hydrogenated styrene elastomer resin layer 19A and/or the polyolefin layer 19B. In general, the additives and the hydrogenated styrene elastomer resin layer 19A (or the polyolefin layer 19B) have a weight ratio of less than about 10:100, or of about 0.1:100 to 10:100, or of about 5:100 to 10:100. An overly high amount of the additives will destroy the processibility of the hydrogenated styrene elastomer resin layer 19A (or the polyolefin layer 19B).

Below, the exemplary embodiments will be described in detail with reference to the accompanying drawings so as to be easily realized by a person having ordinary knowledge in the art. The inventive concepts may be embodied in various forms without being limited to the exemplary embodiments set forth herein. Descriptions of well-known parts are omitted for clarity, and like reference numerals refer to like elements throughout.

### EXAMPLES

### Example 1

100 kg of hydrogenated styrene elastomer resin (LS611 commercially available from Asahi chemical Co. Ltd., melt index of 5.4 g/10 min) and 9 kg of titanium oxide (R706 commercially available from Dupont) were blended and pelletized by a twin-screw blender.

100 kg of a polypropylene (K8002 commercially available from Formosa chemicals and fiber Co., melt index of 1.2 g/10 min) and 9 kg of titanium oxide (R706 commercially available from Dupont) were blended and pelletized by a twin-screw blender.

The blended hydrogenated styrene elastomer resin/titanium oxide pellets and the blended polypropylene/titanium oxide pellets were put into different feed ports of a tri-axial extruder to be extruded to form a back sheet. The back sheet is a layered structure of a hydrogenated styrene elastomer resin/titanium oxide film attached onto a polypropylene/titanium oxide film. Physical properties of the back sheet are tabulated in Table 1.

### Example 2

Example 2 is similar to Example 1, and the difference in Example 2 is that the polypropylene K8002 was replaced with propylene K8009 (commercially available from Formosa chemicals and fiber Co., melt index of 7.5 g/10 min). The other compositions and manufacturing processes of the back sheet were similar to that in Example 1. Physical properties of the back sheet are tabulated in Table 1.

### Example 3

Example 3 is similar to Example 1, and the difference in Example 3 is that the polypropylene K8002 was replaced with propylene YUNGSOX. 2100M (commercially available from Formosa plastics Co., melt index of 7.5 g/10 min). The other compositions and manufacturing processes of the back sheet were similar to that in Example 1. Physical properties of the back sheet are tabulated in Table 1.

### Comparative Example 1

Physical properties of a commercially available back sheet (Protekt HD commercially available from Medico, tetra-layered structure of 13 μm Protekt coating/127 μm PET/adhesive/100 μm EVA) are tabulated in Table 1.

### Comparative Example 2

Physical properties of a commercially available back sheet (Icosolar AAA 3554 commercially available from Isovota, tri-layered structure of polyamide/polyamide/polyamide) are tabulated in Table 1.

### Comparative Example 3

Physical properties of a commercially available back sheet (Icosolar AAA 3552 commercially available from Isovota, tri-layered structure of polyamide/PET/polyamide) are tabulated in Table 1.

TABLE 1

| | Comparative | Comparative | Comparative | | | |
|---|---|---|---|---|---|---|
| | Example 1 | Example 2 | Example 3 | Example 1 | Example 2 | Example 3 |
| Thickness (mm) | 0.27 | 0.395 | 0.365 | 0.376 | 0.467 | 0.451 |
| Breaking voltage⁶ | 12 | 12.5 | 12.4 | 16.7 | 17.4 | 17 |
| (kV) | | | | | | |
| Water | 1.6 | 1.3 | 0.8 | 0.4 | 0.2 | 0.2 |
| permeability rate² | | | | | | |
| (g/m² · day) | | | | | | |
| Reflectivity³ (%) | 85 | 94 | 89 | 85 | 87 | 87 |
| Volume | 7.38E+15 | 6.88E+12 | 1.85E+15 | 7.89E+15 | 5.9E+15 | 8.45E+16 |
| Resistivity¹ (Ω · | | | | | | |
| cm) | | | | | | |
| Maximum load | 68 | 34 | 109 | 32 | 32 | 33 |
| point stress⁴ | | | | | | |
| (MPa) | | | | | | |
| Elongation at | 26 | 185 | 60 | 417 | 423 | 427 |
| break⁴ (%) | | | | | | |
| Peeling force to | 59.62 | 41.2 | 52.57 | 65.58 | 65.61 | 75.81 |
| an EVA layer at | | | | | | |
| room temperature | | | | | | |
| (about 25° C.)⁵ | | | | | | |
| (average load, | | | | | | |
| N/cm) | | | | | | |
| Peeling force to | 38.66 | 2.2 | 26.35 | 65.19 | 64.13 | 76.92 |
| an EVA layer after | | | | | | |
| water boiled at | | | | | | |
| 90° C. for 48 | | | | | | |
| hours⁵ (average | | | | | | |
| load, N/cm) | | | | | | |
| Peeling force to | 54.04 | 36.9 | 57.17 | 63.68 | 69.33 | 76.69 |
| an EVA layer after | | | | | | |
| frozen at 6° C. for | | | | | | |
| 24 hours⁵ (average | | | | | | |
| load, N/cm) | | | | | | |
| Thickness ratio of | none | none | none | 3.91:1 | 4.47:1 | 4.7:1 |
| PP/hydrogenated | | | | | | |
| styrene elastomer | | | | | | |
| resin⁷ (mm/mm) | | | | | | |

Note:
¹Measured with the standard ASTM D257-07 by the equipments HIOKI SM-8220 and HIOKI SME-8311.
²Measured with the standard ASTM F1249-06 by the equipment Mocon 3/60.
³Measured by UV-VIS spectrometer Hitatch U-3010.
⁴Measured with the standard ASTM 1876-01 by universal testing machine.
⁵Measured with the standard ASTM D-1876-BS-EVA-BS by universal testing machine.
⁶Measured with the standard ASTM D149 by the equipment Hipotronic Model: 730-1.
⁷Measured by the scanning electron microscopy (SEM).

As shown in the comparison in Table 1, the back sheets of Examples 1 to 3 had better physical properties and higher peeling force to the EVA than the commercially available back sheets of Comparative Examples 1 to 3. For example, the back sheets of Examples 1 to 3 had breaking voltages of about 16 kV to 18 kV, water permeabilities of about 0.2 g/m²·day to 0.4 g/m²·day, elongation at break of about 400% to 450%, peeling forces of 60N/cm to 80N/cm to an EVA layer at room temperature, peeling forces of 60N/cm to 80N/cm to an EVA layer at high temperature (about 90° C.) and high humidity, and peeling forces of 60N/cm to 80N/cm to an EVA layer at room temperature after a low temperature treatment (about 6° C.).

It will be apparent to those skilled in the art that various modifications and variations can be made to the disclosed methods and materials. It is intended that the specification and examples be considered as exemplary only, with a true scope of the disclosure being indicated by the following claims and their equivalents.

What is claimed is:

1. A module structure, comprising:
a front sheet;
a back sheet opposite to the front sheet;
an optotronic device disposed between the front sheet and the back sheet;
a first encapsulate layer disposed between the optotronic device and the front sheet; and
a second encapsulate layer disposed between the optotronic device and the back sheet,
wherein the back sheet is a layered structure of a hydrogenated styrene elastomer resin layer and a polyolefin layer, and the hydrogenated styrene elastomer resin layer is disposed between the second encapsulate layer and the polyolefin layer.

2. The module structure as claimed in claim 1, wherein the hydrogenated styrene elastomer resin layer comprises poly(styrene-b-isoprene), poly(styrene-b-isoprene-b-styrene, poly(styrene-b-butadiene-b-styrene), poly(styrene-b-isoprene/butadiene-b-styrene, or a polystyrene block and a vinyl bonded rich polyisoprene block.

3. The module structure as claimed in claim 1, wherein the hydrogenated styrene elastomer resin layer contains about 10 wt % to 35 wt % of a polystyrene block.

4. The module structure as claimed in claim 1, wherein the hydrogenated styrene elastomer resin layer has a melt index of about 1.0 g/10 min to 8.0 g/10 min.

5. The module structure as claimed in claim 1, wherein the first encapsulate layer and the second encapsulate layer comprises an ethylene-vinylene acetate copolymer.

6. The module structure as claimed in claim 1, wherein the polyolefin layer comprises polyethylene, polypropylene, ethylene-propylene copolymer, or multi-layered structures thereof.

7. The module structure as claimed in claim 1, wherein the polyolefin layer has a melt index of about 1.0 g/10 min to 8.0 g/10 min.

8. The module structure as claimed in claim 1, wherein the back sheet has a thickness of about 0.2 mm to 0.6 mm.

9. The module structure as claimed in claim 1, wherein the hydrogenated styrene elastomer resin layer and the polyolefin layer have a thickness ratio of about 1:1 to 1:10.

10. The module structure as claimed in claim 1, wherein the optotronic device comprises a solar cell, an organic light emitting diode, or a liquid crystal display device.
